(19) United States
(12) Patent Application Publication
(10) Pub. No.: US 2020/0348227 A1
(43) Pub. Date: Nov. 5, 2020

(54) CARBON ISOTOPE ANALYSIS DEVICE AND CARBON ISOTOPE ANALYSIS METHOD

(71) Applicants: SEKISUI MEDICAL CO., LTD., Tokyo (JP); NATIONAL UNIVERSITY CORPORATION TOKAI NATIONAL HIGHER EDUCATION AND RESEARCH SYSTEM, Aichi (JP)

(72) Inventors: Atsushi SATOU, Tokyo (JP); Tetsuo IGUCHI, Aichi (JP); Hideki TOMITA, Aichi (JP); Norihiko NISHIZAWA, Aichi (JP)

(73) Assignees: SEKISUI MEDICAL CO., LTD., Tokyo (JP); NATIONAL UNIVERSITY CORPORATION TOKAI NATIONAL HIGHER EDUCATION AND RESEARCH SYSTEM, Aichi (JP)

(21) Appl. No.: 16/960,763

(22) PCT Filed: Jan. 22, 2019
(86) PCT No.: PCT/JP2019/001906

§ 371 Date: Jul. 8, 2020

(30) Foreign Application Priority Data
Jan. 22, 2018 (JP) 2018-007874

(51) Int. Cl. G01N 21/3504; H01S 5/34; G02F 1/355; G02F 1/35

(52) U.S. Cl. CPC G01N 21/3504; H01S 5/3402; G01N 2201/06113; G02F 1/3534; G01N 2201/084; G02F 1/3551

(57) ABSTRACT

Provided are a carbon isotope analysis device high in partial pressure of carbon dioxide isotope in gas sent into as optical resonator, and high in sensitivity performance and analytical accuracy, and an analysis method by use of the carbon isotope analysis device. A carbon isotope analysis device including a carbon dioxide isotope generator provided with a combustion unit that generates gas containing carbon dioxide isotope from carbon isotope, and a carbon dioxide isotope purifying unit; a spectrometer including an optical resonator having a pair of mirrors, and a photodetector that determines intensity of light transmitted from the optical resonator; a carbon dioxide trap including a cooler for freezing the carbon dioxide isotope, the carbon dioxide trap being disposed between the carbon dioxide isotope generator and the spectrometer; and a light generator.

### TECHNICAL FIELD

The present invention relates to a carbon isotope analysis device and a carbon isotope analysis method. In particular, the present invention relates to a light generator useful for analysis of radioactive carbon isotope ¹⁴C and the like, which generates narrow-line-width and high-intensity light, and a purifier and a method for a radioactive carbon isotope-containing gas as an analytical gas object, for use in a radioactive carbon isotope analysis device and a radioactive carbon isotope analysis method, by use of the light generator.

### BACKGROUND ART

Carbon isotope analysis has been applied to a variety of fields, including assessment of environmental dynamics based on the carbon cycle, and historical and empirical research through radiocarbon dating. The natural abundances of carbon isotopes, which may vary with regional or environmental factors, are as follows: 98.89% for ¹²C (stable isotope), 1.11% for ¹³C (stable isotope), and 1×10⁻¹³% for ¹⁴C (radioisotope). These isotopes, which have different masses, exhibit the same chemical behavior. Thus, artificial enrichment of an isotope of low abundance and accurate analysis of the isotope can be applied to observation of a variety of reactions.

In the clinical field, in vivo administration and analysis of a compound labeled with, for example, radioactive carbon isotope ¹⁴C are very useful for assessment of drug disposition. For example, such a labeled compound is used for practical analysis in Phase I or Phase IIa of the drug development process. Administration of a compound labeled with radioactive carbon isotope ¹⁴C (hereinafter may be referred to simply as “¹⁴C”) to a human body at a very small dose (hereinafter may be referred to as “microdose”) (i.e., less than the pharmacologically active dose of the compound) and analysis of the labeled compound are expected to significantly reduce the lead time for a drug discovery process because the analysis provides findings on drug efficacy and toxicity caused by drug dispositon.

Examples of the traditional ¹⁴C analysis include liquid scintillation counting (hereinafter may be referred to as “LSC”) and accelerator mass spectrometry (hereinafter may be referred to as “AMS”).

LSC involves the use of a relatively small table-top analyzer and thus enables convenient and rapid analysis. Unfortunately, LSC cannot be used in clinical trials because of its low JAC detection sensitivity (10 dpm/mL). In contrast, AMS can be used in clinical trials because of its high ¹⁴C detection sensitivity (0.001 dpm/mL), which is less than one thousandth of that of LSC. Unfortunately, the use of AMS is restricted because AMS requires a large and expensive analyzer. For example, since only around fifteens of AMS analyzers are provided in Japan, analysis of one sample requires about one week due to a long waiting time for samples to be analyzed. Thus, a demand has arisen for development or a convenient and rapid method of analyzing ¹⁴C.

Some techniques have been proposed for solving the above problems (see for example, Non-Patent Document 1 and Patent Document 1).

I. Galli, et al. reported the analysis of ¹⁴C of a natural isotope abundance level by cavity ring-down spectroscopy (hereinafter may be referred to as “CRDS”) in Non-Patent Document 1, and this analysis has received attention.

Unfortunately, the ¹⁴C analysis by CRDS involves the use of a 4.5-μm laser source having a very intricate structure. Thus, a demand has arisen for a simple and convenient apparatus or method for analyzing 14C.

### RELATED ART

### Patent Documents

Patent Document 1: Japanese Patent No. 3390755
Patent Document 2: Japanese Patent No. 6004412

### Non-Patent Document

Non-Patent Document 1: I. Galli et al., Phy. Rev. Lett. 2011, 107, 270802

### SUMMARY OF INVENTION

### Technical Problem

The present inventors have made studies in order to solve the above problems, and as a result, have proposed a simple and convenient carbon isotope analysis device and analysis method by use of an optical comb as a light source (see Patent Document 2).

However, there has arisen an additional object for an increase in partial pressure of carbon dioxide isotope in gas sent into an optical resonator for the purpose of further increases in sensitivity performance and analytical accuracy.

An object of the present invention is to provide a carbon isotope analysis device high in partial pressure of carbon dioxide isotope in gas sent into and mixed in an optical resonator, and high in sensitivity performance and analytical accuracy, and an analysis method by use of the carbon isotope analysis device.

### Solution to Problem

The present invention relates to the following aspect:
<1> A carbon isotope analysis device including: a carbon dioxide isotope generator provided with a combustion unit that generates gas containing carbon dioxide isotope from carbon isotope, and a carbon dioxide isotope purifying unit; a spectrometer including an optical resonator having a pair of mirrors, and a photodetector that determines intensity of light transmitted from the optical resonator; a carbon dioxide trap including a cooler for freezing the carbon dioxide isotope, the carbon dioxide trap being disposed between the carbon dioxide isotope generator and the spectrometer; and a light generator.
<2> A carbon isotope analysis device including: a carbon dioxide isotope generator provided with a combustion unit that generates gas containing carbon dioxide isotope from carbon isotope, and a carbon dioxide isotope purifying unit, the carbon dioxide isotope purifying unit including a gaseous contaminant separating unit, a concentrating unit of the carbon dioxide isotope, and a dehumidifying unit; a spectrometer including an optical resonator having a pair of mirrors and a cooler for prevention of noise generation, and a photodetector that determines intensity of light transmitted from the optical resonator; a carbon dioxide trap including a cooler for freezing the carbon dioxide isotope, the carbon dioxide trap being disposed between the carbon dioxide isotope generator and the spectrometer; and a light generator.
<3> The carbon isotope analysis device according; to <1> or <2>, wherein the light generator includes a ht generator including a single light source, a splitter that splits light from the light source, a condenser lens that focuses light from the splitter, and a mirror that reflects light from the condenser lens to send the light back to the light source via the condenser lens and the splitter.
<4> The carbon isotope analysis device according to <1> or <2>, wherein the light generator includes a light generator body having a main light source and an optical fiber that transmits light from the main light source; and a beat signal measurement device including an optical comb source that generates an optical comb made of a flux of narrow-line-width light beams where the wavelength region of a ht beam is 4500 nm to 4800 nm, an optical fiber for beat signal measurement, the optical fiber transmitting light from the optical comb source, a splitter that is disposed on the optical fiber that transmits light from the main light source, an optical fiber that allows light from the main light source to be partially split and transmitted to the optical fiber for beat signal measurement via the splitter, and a photodetector that measures a beat signal generated due to the difference in frequency between light from the main light source and light from the optical comb source.
<5> The carbon isotope analysis device according to <4>, wherein the light source is a mid-infrared quantum cascade laser.
<6> The carbon isotope analysis device according to <1> or <2>, wherein the light generator includes a single light source; a first optical fiber that transmits first light from the light source; a second optical fiber that generates second light of a longer wavelength than the first light, the second optical fiber splitting from a splitting node of the first optical fiber and coupling with the first optical fiber at a coupling node downstream; a first amplifier that is disposed between the splitting node and the coupling node of the first optical fiber; a second amplifier that is disposed between the splitting node and the coupling node of the second optical fiber and that is different in band from the first amplifier; and a nonlinear optical crystal that allows a plurality of light beams different in frequency to propagate through to thereby generate a mid-infrared optical frequency comb of a wavelength range from 4.5 μm to 4.8 μm, from the difference in frequency, as light at an absorption wavelength of the carbon dioxide isotope.
<7> A carbon isotope analysis method, including the steps of: generating carbon dioxide isotope from carbon isotope; cooling a carbon dioxide trap to 0° C. or less; sending the carbon dioxide isotope and gas containing carrier gas lower in freezing point than the carbon dioxide isotope, into the carbon dioxide trap, thereby condensing the carbon dioxide isotope; removing gas in the carbon dioxide trap; heating the carbon dioxide trap with the carbon dioxide trap being shielded from the outside, thereby gasifying the condensed carbon dioxide isotope; filling an optical resonator with the gasified carbon dioxide isotope; generating a mid-infrared optical frequency comb of a wavelength range from 4.5 μm to 4.8 μm, as irradiation light at an absorption wavelength of the carbon dioxide isotope; measuring the intensity of the transmitted light generated by resonance of the carbon dioxide isotope excited by the irradiation light; and calculating the concentration of the carbon isotope from the intensity of the transmitted light.
<8> The carbon isotope analysis method according to <7>, wherein the carbon dioxide trap is cooled to the freezing point or less, of the carbon dioxide isotope in the cooling step.
<9> The carbon isotope analysis method according to <7> or <8>, wherein the carrier gas is helium (He) gas.

### Advantageous Effects of Invention

The present invention provides a carbon isotope analysis device high in partial pressure of carbon dioxide isotope in gas sent into an optical resonator, and higher in sensitivity performance and analytical accuracy, and an analysis method by use of the carbon isotope analysis device.

### BRIEF DESCRIPTION OF DRAWINGS

FIG. 1 is a conceptual view of a first embodiment of a carbon isotope analysis device.

FIG. 2 is a conceptual view of an embodiment of a carbon isotope trapping system.

FIG. 3 illustrates absorption spectra in the 4.5-μm wavelength range of ¹⁴CO₂ and competitive gases.

FIGS. 4A and 4B illustrate the principle of high-rate scanning cavity ring-down absorption spectroscopy using laser beam.

FIG. 5 illustrates the temperature dependence of absorption Δβ of ¹³CO₂ and ¹⁴CO₂ in CRDS.

FIG. 6 is a conceptual view of a modification of the optical resonator.

FIG. 7 illustrates the relation between the absorption wavelength and the absorption intensity of an analytical sample.

FIG. 8 is a conceptual view of a delay line.

FIG. 9 illustrates the principle of mid-infrared comb generation by use of one optical fiber.

FIG. 10 is a conceptual view of a second embodiment of a carbon isotope analysis device.

FIG. 11 illustrates an Er-doped fiber-laser-based mid-infrared (MIR) comb generation system 1.

FIG. 12 is a conceptual view of a third embodiment of a carbon isotope analysis device.

FIGS. 13A, 13B, and 13C each illustrate a flow diagram of a light generator of a third carbon isotope analysis device.

FIG. 14 is a conceptual view of a fourth embodiment of a carbon isotope analysis device.

FIG. 15 illustrates an advantage of a carbon dioxide trap.

### DESCRIPTION OF EMBODIMENTS

The present invention will now be described by way of embodiments, which should not be construed to limit the present invention. In the drawings, the same or similar reference signs are assigned to components having the same or similar functions without redundant description. It should be noted that the drawings are schematic and thus the actual dimensions of each component should be determined in view of the following description. It should be understood that the relative dimensions and ratios between the drawings may be different from each other.

### [First Aspect of Carbon Isotope Analysis Device]

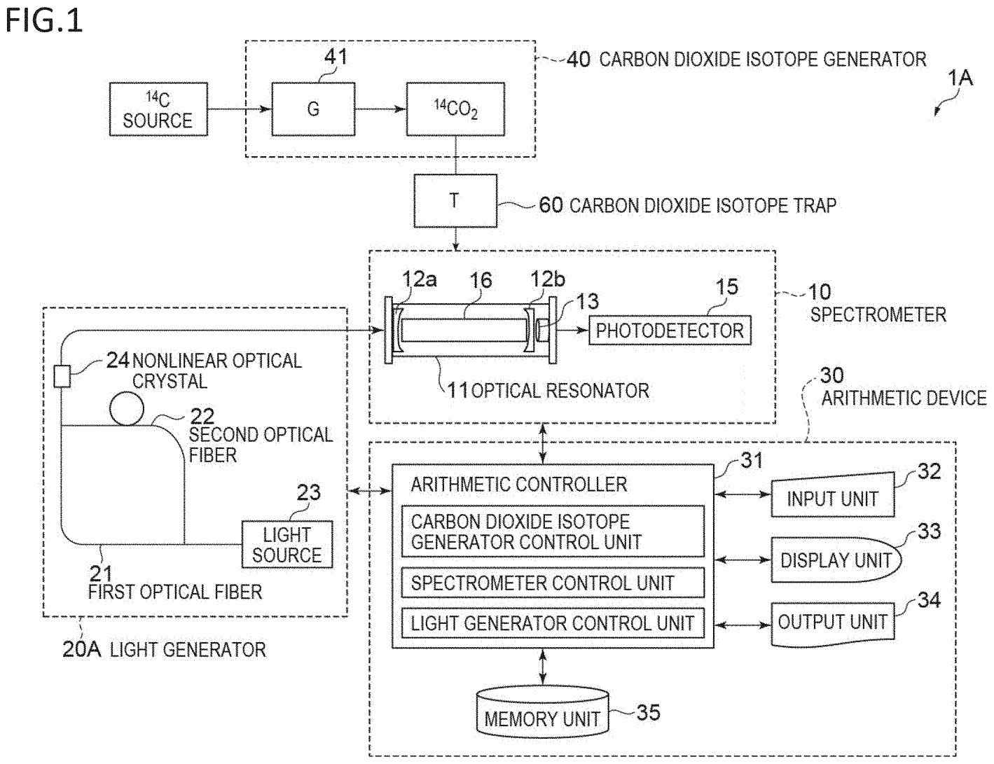

FIG. 1 is a conceptual view of a carbon isotope analysis device according to a first aspect. As illustrated in FIG. 1, a carbon isotope analysis device 1 includes a carbon dioxide isotope generator 40, a spectrometer 10, a carbon dioxide trap 60 and a light generator 20A, and also an arithmetic device 30.

The carbon dioxide isotope generator 40 includes a combustion unit that generates gas containing carbon dioxide isotope from carbon isotope, a carbon dioxide isotope purifying unit, and a measurement unit of the amount of carbon, the measurement unit measuring the total amount of carbon from the amount of carbon dioxide.

The spectrometer 10 includes an optical resonator 11 having a pair of mirrors 12a and 12b, and a photodetector 15 that determines the intensity of light transmitted from the optical resonator 11.

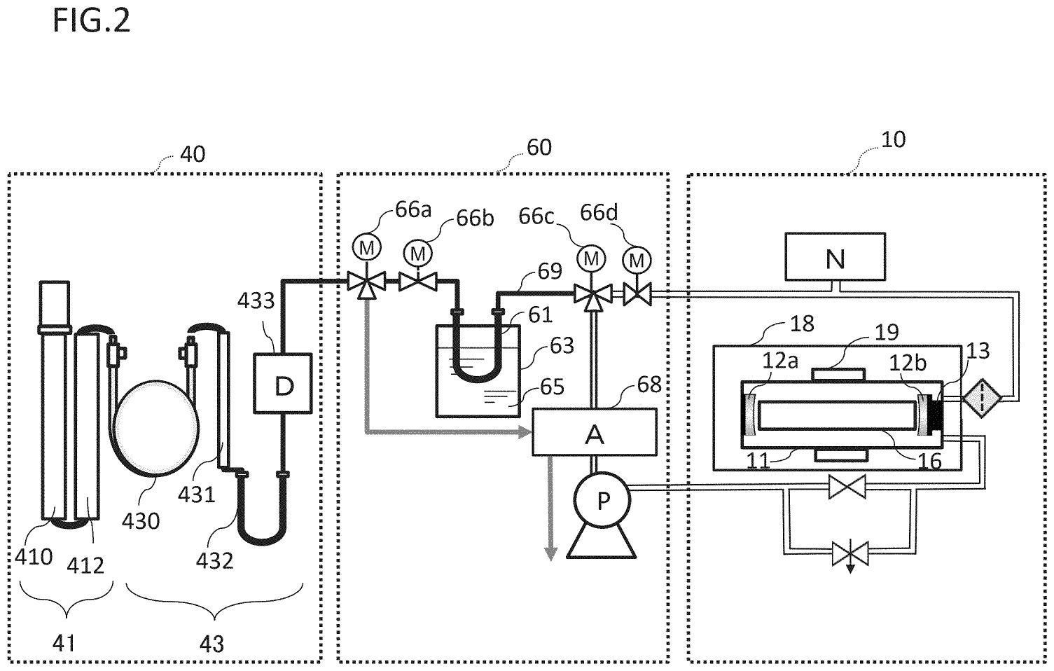

FIG. 2 is a conceptual view of a carbon dioxide trapping system. As illustrated in FIG. 2, a carbon dioxide trap 60 includes a gas supply tube 69 that allows carbon dioxide isotope to be sent from the carbon dioxide isotope generator 40 to the spectrometer 10, valves 66a and 66b that are disposed upstream of the gas supply tube 69, a U-shaped trap tube 61, valves 66c and 66d that are disposed downstream of the gas supply tube 69, a pump P that is disposed by splitting at the valve 66c from the gas supply tube 69, the pump allowing the gas supply tube 69 and the resonator 11 to be at negative pressure, and a Dewar flask 63 which can be filled with liquid nitrogen 65 for cooling the trap tube 61.

Not only operation of the pump P, but also control of opening and closing of the valves 66a to 66d enables introduction of carbon dioxide isotope generated in the carbon dioxide isotope generator into the optical resonator 11 to be controlled.

In this embodiment, a radioisotope ¹⁴C, carbon isotope will be exemplified as an analytical sample. The light having an absorption wavelength range of the carbon dioxide isotope ¹⁴CO₂ generated from the radioisotope ¹⁴C is light of a 4.5-μm wavelength range. The combined selectivity of the absorption line of the target substance, the light generator, and the optical resonator mode can achieve high sensitivity (detail is described later).

Throughout the specification, the term “carbon isotope” includes stable isotopes ¹²C and ¹³C and radioactive isotopes ¹⁴C, unless otherwise specified. In the case that the elemental signature “C” is designated, the signature indicates a carbon isotope mixture in natural abundance.

Stable isotopic oxygen includes ¹⁶O, ¹⁷O and ¹⁸O and the elemental signature “O” indicates an isotopic oxygen mixture in natural abundance.

The term “carbon dioxide isotope” includes ¹²CO₂, ¹³CO₂ and ¹⁴CO₂, unless otherwise specified. The signature “CO₂” includes carbon dioxide molecules composed of carbon isotope and isotopic oxygen each in natural abundance.

Throughout the specification, the term “biological sample” includes blood, plasma, serum, urine, feces, bile, saliva, and other body fluid and secretion; intake gas, oral gas, skin gas, and other biological gas; various organs, such as lung, heart, liver, kidney, brain, and skin, and crushed products thereof. Examples of the origin of the biological sample include all living objects, such as animals, plants, and microorganisms; preferably, mammals, preferably human beings. Examples of mammals include, but, should not be limited to, human beings, monkey, mouse, rat, guinea pig, rabbit, sheep, goat, horse, cattle, pig, dog, and cat.

### <Carbon Dioxide Isotope Generator>

The carbon dioxide isotope generator 40 may be of any type that can convert carbon isotope to carbon dioxide isotope. The carbon dioxide isotope generator 40 should preferably have a function to oxidize a sample and to convert carbon contained in the sample to carbon dioxide.

The carbon dioxide isotope generator 40 may be a carbon dioxide generator (G) 41, for example, a total organic carbon (TOC) gas generator, a sample gas generator for gas chromatography, a sample gas generator for combustion ion chromatography, or an elemental analyzer (EA).

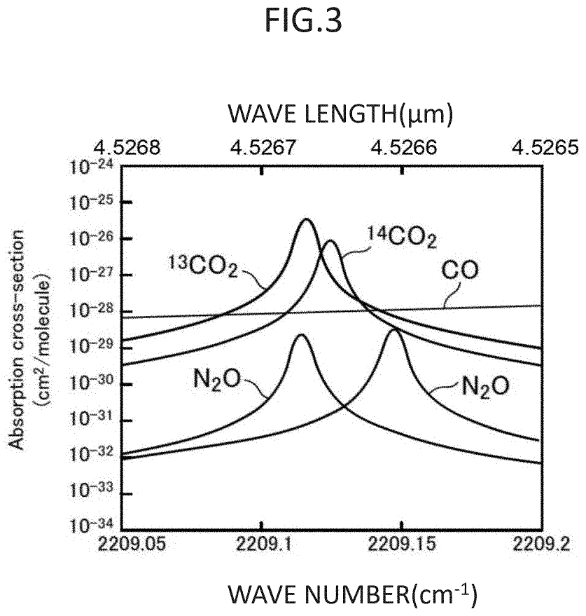

FIG. 3 is 4.5-μm wavelength range absorption spectra of ¹⁴CO₂ and competitive gases ¹³CO₂, CO, and N₂O under the condition of a CO₂ partial pressure of 20%, a CO partial pressure of 1.0×10⁻⁴% and a N₂O partial pressure of 3.0×10⁻⁸% at 273K.

Gas containing carbon dioxide isotope ¹⁴CO₂ (hereinafter merely “¹⁴CO₂”) can be generated through combustion of a pretreated biological sample; however, gaseous contaminants, such as CO and N₂O are generated together with ¹⁴CO₂ in this process. CO and N₂O each exhibit a 4.5-μm wavelength range absorption spectrum as illustrated in FIG. 3 and interfere with the 4.5-μm wavelength range absorption spectrum assigned to ¹⁴CO₂. Thus, Co and N₂O should preferably be removed for improved analytical sensitivity.

A typical process of removing CO and N₂O involves collection and separation of ¹⁴CO₂ as described below. The process may be combined with a process of removing or reducing CO and N₂O with an oxidation catalyst or platinum catalyst.

As illustrated in FIG. 2, a combustion unit 41 of the carbon dioxide isotope generator 40 should preferably include a combustion tube 410, a heating unit (not illustrated) that can heat the combustion tube, and a reduction unit 412. A carbon dioxide isotope purifying unit 43 should preferably include a drier 430, an adsorbent 431, a thermal desorption column 432, and a detector 433.

Preferably, the combustion tube 410 is configured from refractory glass (such as quartz glass) so as to be able to accommodate a sample therein and is provided with a sample port formed on a part thereof. Besides the sample port, a carrier gas port through which carrier gas is introduced to the combustion tube may also be formed on the combustion tube. Herein, not only such an aspect where the sample port and the Hike are provided on a part of the combustion tube, but also a configuration where a sample introducing unit is formed as a separate component from the combustion tube at an end of the combustion tube and the sample port and the carrier gas port are formed on the sample introducing unit, may be adopted.

Examples of the heater include electric furnaces, specifically tubular electric furnaces that can place and heat a combustion tube therein. A typical example of the tubular electric furnace is ARF-30M (available from Asahi Rika Seisakusho).

The combustion tube 410 should preferably be provided with a combustion oxidation unit 410 and/or a reduction unit 412 packed with at least one catalyst, downstream of the carrier gas channel. The combustion oxidation unit and/or the reduction unit may be provided at one end of the combustion tube 41 or provided in the form of a separate component. Examples of the catalyst to be contained in the combustion oxidation unit include copper oxide and a mixture of silver and cobalt oxide. The combustion oxidation unit can be expected to oxidize H₂ and CO generated by combustion of a sample into H₂O and CO₂. Examples of the catalyst to be contained in the reduction unit include reduced copper and a platinum catalyst. The reduction unit can be expected to reduce nitrogen oxide (NOₓ) containing N₂O into N₂.

The carbon dioxide isotope purifying unit 43 may be a thermal desorption column. (CO₂ collecting column) 432 of ¹⁴CO₂ in a gas generated by combustion of a biological sample, for use in gas chromatography (GC). Thus, any influence of CO and/or N₂O at the stage of detection of ¹⁴CO₂ can be reduced or removed. A CO₂ gas containing ¹⁴CO₂ is temporarily collected in a GC column and thus concentration of ¹⁴CO₂ is expected. Thus, it can be expected that the partial pressure of ¹⁴CO₂ increases.

The carbon dioxide isotope purifying unit 43 should preferably include a ¹⁴CO₂ adsorbent 431, for example, soda lime or calcium hydroxide. Thus, ¹⁴CO₂ can be isolated in the form of carbonate to thereby allow the problem of gaseous contaminants to be solved. ¹⁴CO₂ can be retained as carbonate and thus a sample can be temporarily reserved. Herein, phosphoric acid can be used in the discharge.

Such gaseous contaminants can be removed by any of or both (i) Collection and separation of ¹⁴CO₂ by thermal desorption column and (ii) Separation of ¹⁴CO₂ through trapping and discharge of ¹⁴CO₂ with and from ¹⁴CO₂ adsorbent.

(iii) Concentration (Separation) of ¹⁴CO₂

¹⁴CO₂ generated by combustion of the biological sample is diffused in piping. Therefore, ¹⁴CO₂ may also be allowed to adsorb to an adsorbent and be concentrated, resulting in as enhancement is detection sensitivity (intensity). Such concentration can also be expected to separate ¹⁴CO₂ from CO and N₂O.

### <Spectrometer>

With reference to FIG. 1, the spectrometer 10 includes an optical resonator 11 and a photodetector 15 that determines the intensity of the light transmitted from the optical resonator 11. The optical resonator or optical cavity 11 includes a cylindrical body to be filled with the target carbon dioxide isotope; a pair of highly reflective mirrors 12 and 12b respectively disposed at first and second longitudinal end sides of the body such that the concave faces of the mirrors confront each other; a piezoelectric element 13 disposed at the second end side of the body to adjust the distance between the mirrors 12a and 12b; and a cell 16 to be filled with an analyte gas. Although not illustrated, the side of the body is preferably provided with a gas inlet through which the carbon dioxide isotope is injected and a port for adjusting the pressure in the body. Herein, the pair of mirrors 12a and 12b preferably have a reflectance of 99% or more, more preferably 99.99% or more.

A laser beam incident on and confined in the optical resonator 11 repeatedly reflects between the mirrors over several thousand to ten thousand times while the optical resonator 11 emits light at an intensity corresponding to the reflectance of the mirrors. Thus, the effective optical path length of the laser beam reaches several tens of kilometers, and a trace amount of analyte gas contained in the optical resonator can yield large absorption intensity.

The optical resonator may also be CRDS with fiber Bragg grating (FBG) and a gain-switched semiconductor laser or CRDS with an evanescent optical device.

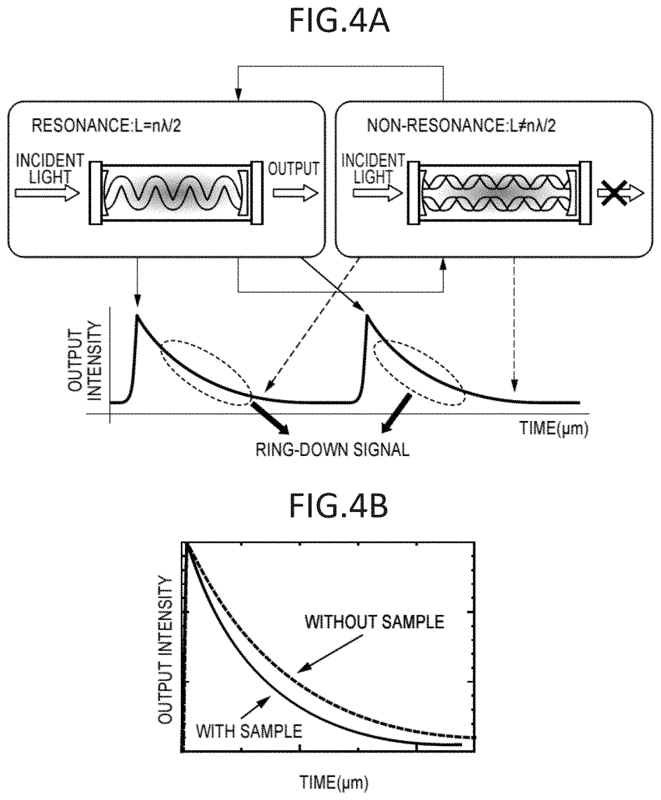

FIGS. 4A and 4B illustrate the principle of high-rate scanning cavity ring-down absorption spectroscopy (hereinafter may be referred to as “CRDS”) using laser beam. As illustrated in FIG. 4A, the optical resonator in a resonance state between the mirrors outputs a high-intensity signal. In contrast, a non-resonance state between the mirrors, by the change through operation of the piezoelectric element 13, does not enable any signal to be detected due to the interference effect of light. In other words, an exponential decay signal (ring-down signal) as illustrated in FIG. 4A can be observed through a rapid change in the length of the optical resonator from a resonance state to a non-resonance state.

In the case of the absence of a light-absorbing substance in the optical resonator, the dotted curve in FIG. 4B corresponds to a time-dependent ring-down signal output from the optical resonator. In contrast, the solid curve in FIG. 4B corresponds to the case of the presence of a light-absorbing substance in the optical resonator. In this case, the light decay time is shortened because of absorption of the laser beam by the light-absorbing substance during repeated reflection of the laser beam in the optical resonator. The light decay time depends on the concentration of the light-absorbing substance in the optical resonator and the wavelength of the incident laser beam. Thus, the absolute concentration of the light-absorbing substance can be calculated based on the Beer-Lambert law ii. The concentration of the light-absorbing substance in the optical resonator may be determined through measurement of a modulation in ring-down rate, which is proportional to the concentration of the light-absorbing substance.

The transmitted light leaked from the optical resonator is detected with the photodetector, and the concentration of ¹⁴CO₂ is calculated with the arithmetic device. The concentration of ¹⁴CO₂ is then calculated from the concentration of ¹⁴CO₂.

The distance between the mirrors 12a and 12b in the optical resonator 11, the curvature radius of the mirrors 12a and 12b, and the longitudinal length and width of the body should preferably be varied depending on the absorption wavelength of the carbon dioxide isotope (i.e., analyte). The length of the resonator is adjusted from 1 mm to 10 m, for example.

In the case of carbon dioxide isotope ¹⁴CO₂, an increase in length of the resonator contributes to enhancement of the effective optical path length, but leads to an increase in volume of the gas cell, resulting in an increase in amount of a sample required for the analysis. Thus, the length of the resonator is preferably 10 cm to 60 cm. Preferably, the curvature radius of the mirrors 12a and 12b is equal to or slightly larger than the length of the resonator.

The distance between the mirrors can be adjusted by, for example, several micrometers to several tens of micrometers through the drive of the piezoelectric element 13. The distance between the mirrors can be finely adjusted by the piezoelectric element 13 for preparation of an optimal resonance state.

The mirrors 12a and 12b (i.e., a pair of concave mirrors) may be replaced with combination of a concave mirror and a planar mirror or combination of two planar mirrors that can provide a sufficient optical path.

The mirrors 12a and 12b may be composed of sapphire glass, Ca, F₂, or ZnSe.

The cell 16 to be filled with the analyte gas preferably has a small volume because even a small amount of the analyte effectively provides optical resonance. The volume of the cell 16 may be 8 ml to 1,000 ml. The cell volume can be appropriately determined depending on the amount of a ¹⁴C source to be analyzed. For example, the cell volume is preferably 80 mL to 120 mL for a ¹⁴C source that is available in a large volume (e.g., urine), and is preferably 8 mL to 12 ml, for a ¹⁴C source that is available only in a small volume (e.g., blood or tear fluid).

Evaluation of Stability Condition of Optical Resonator

The ¹⁴CO₂ absorption and the detection limit of CRDS were calculated based on spectroscopic data. Spectroscopic data on ¹²CO₂ and ¹³CO₂ were retrieved from the high-resolution transmission molecular absorption database (HITRAN), and spectroscopic data on ¹⁴CO₂ were extracted from the reference “S. Dobos, et al., 3. Naturforsch, 44a, 633-639 (1989)”.

A Modification (Δβ) in ring-down rate (exponential decay rate) caused by ¹⁴CO₂ absorption (Δβ=β−β₀ where β is a decay rate in the presence of a sample, and β⁰ is a decay rate in the absence of a sample) is represented by the following expression:

Δβ=σ₁₄(λ,T,P)N(T,P,X₁₄)c

where σ₁₄, represents the photoabsorption cross section of ¹⁴CO₂, N represents the number density of molecules, c represents the speed of light, and σ₁₄ and N are the function of λ (the wavelength of laser beam), T (temperature), P (pressure), and X₁₄=ratio ¹⁴C/^{Total}C.

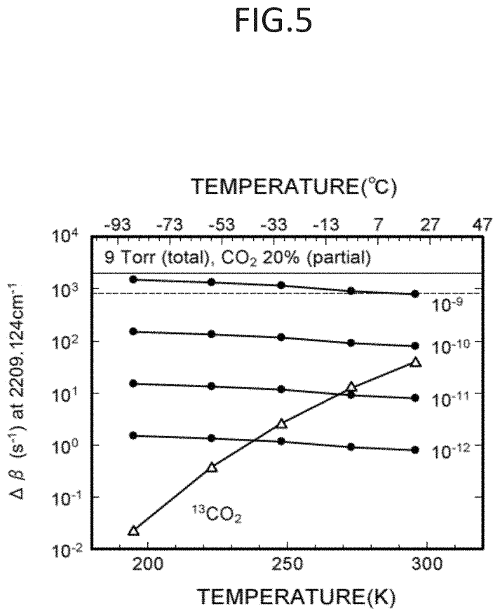

FIG. 5 illustrates the temperature dependence of calculated Δβ due to ¹³CO₂ absorption or ¹⁴CO₂ absorption. As illustrated in FIG. 5, ¹³CO₂ absorption is equal to or higher than ¹⁴CO₂ absorption at 300K (room temperature) at a ¹⁴C/^{Total}C of 10⁻¹⁰, 10⁻¹¹, or 10⁻¹², and thus the analysis requires cooling in such a case.

If a modification (Δβ) in ring-down rate (corresponding to noise derived from the optical resonator) can be reduced to a level on the order of 10¹ s⁻¹, the analysis could be performed at a ratio ¹⁴C/^{Total}C on the order of 10⁻¹¹. Thus, cooling at about −40° C. is revealed to be most preferable during the analysis.

In the case of a ratio ¹⁴C/^{Total}C of 10⁻¹¹ as a lower detection limit, the drawing suggests that requirements involve an increase (for example, 20%) in partial pressure of CO₂ gas due to concentration of the CO₂ gas and the temperature condition described above.

The cooler and the cooling temperature will be described in more detail in the section of a second aspect of the carbon isotope analysis device, described below.

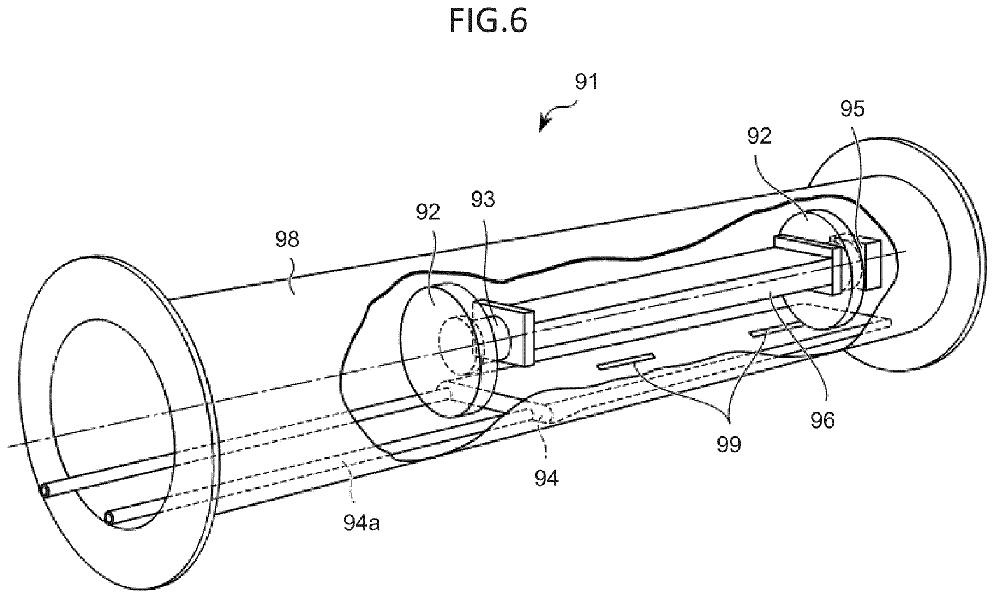

FIG. 6 illustrates a conceptual view (partially cross-sectional view) of a modification of the optical resonator 11 described. As illustrated in FIG. 6, an optical resonator 91 includes a cylindrical adiabatic chamber (vacuum device) 98, a gas cell 96 for analysis disposed in the adiabatic chamber 98, a pair of highly reflective mirrors 92 disposed at two ends of the gas cell 96, a mirror driving mechanism 95 disposed at one end of the gas cell 96, a ring piezoelectric actuator 93 disposed on the other end of the gas cell 96, a Peltier element 99 for cooling the gas cell 96, and a water-cooling heatsink 94 provided with a cooling pipe 94a connected to a circulation coiler (not illustrated). The water-cooling heatsink 94 can release heat emitted from the Peltier element 99.

### <Light Generator>

The light generator 20A of FIG. 1 may be of any type that can generate light having the absorption wavelength of the carbon dioxide isotope. In this embodiment, a compact light generator will be described that can readily generate light of a 4.5-μm wavelength range, which is the absorption wavelength of radioactive carbon dioxide isotope ¹⁴CO₂.

The light source 23 is preferably an ultrashort pulse generator. In the case of use of an ultrashort pulse generator as the light source 23, a high photon density per pulse enables a nonlinear optical effect to be easily exerted, simply generating light of a 4.5-μm wavelength range corresponding to an absorption wavelength of radioactive carbon dioxide isotope ¹⁴CO₂. A flux of comb-like light beams uniform in width of each wavelength. (optical frequency comb, hereinafter may be referred to as “optical comb”.) is obtained, and thus the variation in oscillation wavelength can be negligibly small. In the case of a continuous oscillation generator as the light source, the variation in oscillation wavelength causes a need for measurement of the variation in oscillation wavelength with an optical comb or the like.

The light source 23 can be, for example, a solid-state laser, a semiconductor laser or a fiber laser that generates short pulse by mode-locking. In particular, a fiber laser is preferably used because a fiber laser is a practical light source that is compact and also excellent in stability to environment.

Such a fiber laser can be an erbium (Er)-based (1.55-μm wavelength range) or ytterbium. (Yb)-based (1.04-μm wavelength range) fiber laser. An Er-based fiber laser is preferably used from the viewpoint of economics, and an Yb-based fiber laser is preferably used from the viewpoint of an enhancement in intensity of light.

A plurality of optical fibers 21 and 22 can be a first optical fiber 21 that transmits light from the light source and a second optical fiber 22 for wavelength conversion, the second optical fiber splitting from the first optical fiber 21 and coupling with the first optical fiber 21 downstream. The first optical fiber 21 can be any one connected from the tight source to the optical resonator. A plurality of optical components and a plurality of optical fibers can be disposed on each path of the optical fibers.

It is preferred that the first optical fiber 21 can transmit high intensity of ultrashort light pulses without deterioration of the optical properties of the pulses. Specific examples can include a dispersion-compensating fiber (DC) and a double-clad fiber. The first optical fiber 21 should preferably be composed of fused silica.

It is preferred that the second optical fiber 22 can efficiently generate ultrashort light pulses at a desired longer wavelength and transmit high intensity of ultrashort light pulses without deterioration of the optical properties of the pulses. Specific examples can include a polarization-maintaining fiber, a single-mode fiber, a photonic crystal fiber, and a photonic bandgap fiber. The optical fiber preferably has a length or several meters to several hundred meters depending on the amount of wavelength shift. The second optical fiber 22 should preferably be composed of fused silica.

The nonlinear optical crystal 24 is appropriately selected depending on the incident light and the emitted light. In the present Example, for example, a PPMgSLT (periodically poled MgO-doped Stoichiometric Lithium. Tantalate (LiTaO₃)) crystal, a PPLN (periodically poled Lithium Niobate) crystal, or a GaSe (Gallium selenide) crystal can be used from the viewpoint that light of a about 4.5-μm wavelength range is generated from each incident light. Since a single fiber laser light source is used, perturbation of optical frequency can be cancelled out in difference frequency generation as described below.

The length in the irradiation direction (longitudinal direction) of the nonlinear optical crystal 24 is preferably longer than 11 mm, more preferably 32 mm to 44 mm, because a high-power optical comb is obtained.

Difference frequency generation (hereinafter may be referred to as “DFG”) can be used to generate difference-frequency light. In detail, the light beams of different wavelengths (frequencies) from the first and second optical fibers 21 and 22 transmit through the non-linear optical crystal, to generate difference-frequency light based on the difference in frequency. In the present. Example, two light beams having wavelengths λ₁ and λ₂ are generated with the single light source 23 and extracted into the nonlinear optical crystal, to generate light in the absorption wavelength of carbon dioxide isotope based on the difference in frequency. The conversion efficiency of the DFG using the nonlinear optical crystal depends on the photon density of light source having a plurality of wavelengths (λ₁, λ₂, . . . λₓ). Thus, difference-frequency light can be generated from a single pulse laser light source through DFG.

The resultant 4.5-μm wavelength range light is an optical comb composed of a spectrum of frequencies (modes) with regular intervals (fᵣ) each corresponding to one pulse (frequency f=f^{ceo}+N·fᵣ, N: mode number). CRDS using the optical comb requires extraction of light having the absorption wavelength of the analyte into an optical resonator including the analyte. Herein, f is cancelled out and thus f_{ceo} is 0 in the optical comb generated, according to a process of difference frequency generation.

The light source may generate laser beams having different wavelengths from two laser devices (Nd:YAG laser and external-cavity diode laser (ECDL)) and generate irradiation light having the absorption wavelength of the carbon dioxide isotope based on the difference in frequency between these laser beams.

The light generator is preferably configured from a single fiber laser light source, an optical fiber having a length of several meters, and a nonlinear optical crystal. The reason is because the light generator having such a configuration has a compact size and is easy to carry and operate. Since a plurality of light beams are generated from a single light source, these beams exhibit the same width and timing of perturbation, and thus the perturbation of optical frequency can be readily cancelled through difference frequency generation without a perturbation controller.

In some embodiments, a laser beam may be transmitted through air between the optical resonator and the coupling node of the first optical fiber with the second optical fiber. Alternatively, the optical path between the optical resonator and the coupling node may optionally be provided with an optical transmission device including an optical system for convergence and/or divergence of a laser beam through a lens.

### <Arithmetic Device>

The arithmetic device 30 may be of any type that can determine the concentration of a light-absorbing substance in the optical resonator based on the decay time and ring-down rate and calculate the concentration of the carbon isotope from the concentration of the light-absorbing substance.

The arithmetic device 30 includes an arithmetic controller 31, such as an arithmetic unit used in a common computer system (e.g., CPU) an input unit 32, such as a keyboard or a pointing device (e.g., a mouse) a display unit. 33, such as an image display (e.g., a liquid crystal display or a monitor); an output unit 34, such as a printer; and a memory unit 35, such as a ROM, a RAM, or a magnetic disk.

Although the carbon isotope analysis device according to the first aspect has been described above, the configuration of the carbon isotope analysis device should not be limited to the embodiment described above, and various modifications may be made. Other aspects of the carbon isotope analysis device will now be described by focusing on modified points from the first aspect.

<Cooler and Dehumidifier>

As illustrated in FIG. 2, a spectrometer 10 may further include a Peltier element 19 that cools an optical resonator 11, and a vacuum device 18 that accommodates the optical resonator 11. Since the light absorption of ¹⁴CO₂ has temperature dependence, a decrease in temperature in the optical resonator 11 with the Peltier element 19 facilitates distinction between ¹⁴CO₂ absorption lines and ¹³CO₂ and ¹²CO₂ absorption lines and enhances the ¹⁴CO₂ absorption intensity. The optical resonator 11 is disposed in the vacuum device 18, and thus the optical resonator 11 is not exposed to external air, leading to a reduction in effect of the external temperature on the resonator 11 and an improvement in analytical accuracy.

The cooler for cooling the optical resonator 11 may be, for example, a liquid nitrogen vessel or a dry ice vessel besides the Peltier element 19. The Peltier element 19 is preferably used in view of a reduction in size of a spectrometer 10, whereas a liquid nitrogen vessel or a dry ice vessel is preferably used in view of a reduction in production cost of the device.

The vacuum device 18 may be of any type that can accommodate the optical resonator 11, apply irradiation light from the light generator 20 to the optical resonator 11, and transmit light transmitted, to the photodetector.

A dehumidifier may be provided. Dehumidification may be here carried out with a cooling means, such as a Peltier element, or by a membrane separation method using a polymer membrane, such as a fluorinated ion-exchange membrane, for removing moisture.

In the case that the carbon isotope analysis device 1 is used in a microdose test, the prospective detection sensitivity to the radioactive carbon isotope ¹⁴C is approximately 0.1 dpm/ml. Such a detection sensitivity “0.1 dpm/ml” requires not only use of “narrow-spectrum laser” as a light source, but also the stability of wavelength or frequency of the light source. In other words, the requirements include no deviation from the wavelength of the absorption line and a narrow line width. In this regard, the carbon isotope analysis device 1, which involves CRDS with a stable light source using “optical frequency comb light”, can solve such a problem. The carbon isotope analysis device 1 has an advantage in that the device can determine a low concentration of radioactive carbon isotope in the analyte.

The earlier literature (Hiromoto Kazuo et al., “Designing of ¹⁴C continuous monitoring based on cavity ring down spectroscopy”, preprints of Annual Meeting, the Atomic Energy Society of Japan, Mar. 19, 2010, p. 432) discloses determination of the concentration of ¹⁴C in carbon dioxide by CRDS in relation to monitoring of the concentration of spent fuel in atomic power generation. Although the signal processing using the fast Fourier transformation (FFT) disclosed in the literature has a high processing rate, the fluctuation of the baseline increases, and thus a detection sensitivity of 0.1 dpm/mi cannot be readily achieved.

However, as described above, the present invention allows the partial pressure of carbon dioxide isotope ¹⁴CO₂ is sample gas to be enhanced to thereby allow the prospective detection sensitivity to the radioactive carbon isotope ¹⁴C to be enhanced, thereby enabling a detection sensitivity of “0.1 dpm/ml” to be achieved.

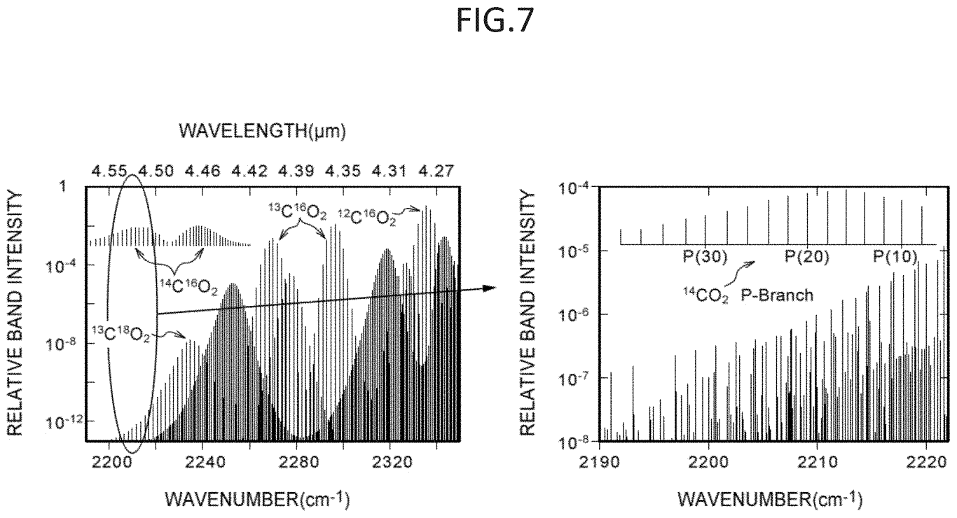

FIG. 7 (cited from Applied Physics Vol. 24, pp. 381-386, 1981) illustrates the relationship between the absorption wavelength and absorption intensity of analytical samples ¹²C¹⁶O₂, ¹³C¹⁸O₂, ¹³C¹⁶O₂, and ¹⁴C¹⁶O₂. As illustrated in FIG. 7, each carbon dioxide isotope has distinct absorption lines. Actual absorption lines have a finite width caused by the pressure and temperature of a sample. The pressure and temperature of a sample are preferably adjusted to atmospheric pressure or less and 273 K (0° C.) or less, respectively.

Since the absorption intensity of ¹⁴CO₂ has temperature dependence, the temperature in the optical resonator 11 is preferably adjusted to a minimum possible level. In detail, the temperature in the optical resonator 11 is preferably adjusted to 273K (0° C.) or less. The temperature may have any lower limit. In view of cooling effect and cost, the temperature in the optical resonator 11 is adjusted to preferably 173K to 253K (−100° C. to −20° C.), more preferably about 233K (−40° C.)

The spectrometer may further be provided with a vibration damper. The vibration damper can prevent a perturbation in distance between the mirrors due to the external vibration, resulting in an improvement in analytical accuracy. The vibration damper may be an impact absorber (polymer gel) or a seismic isolator. The seismic isolator may be of any type that can provide the spectrometer with vibration having a phase opposite to that of the external vibration.

### <Delay Line>

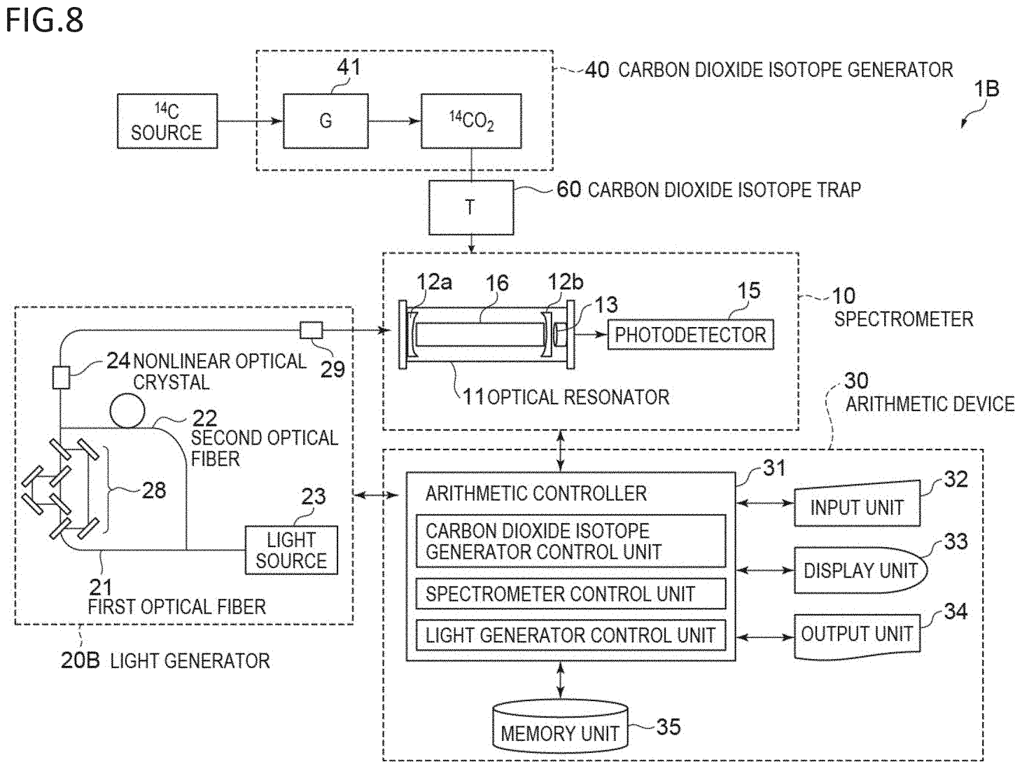

As illustrated in FIG. 8, a delay line 28 (optical path difference adjuster) may be provided on the first optical fiber 21. The delay line 28 includes a wavelength filter that separates light from the light source 23 to a plurality of spectral components, and a wavelength filter that adjusts the relative time delays of the plurality of spectral components and focuses on a nonlinear crystal 24. Thus, fine adjustment of the wavelength of light generated on the first optical fiber 21 is facilitated, and the maintenance of the light generator is facilitated.

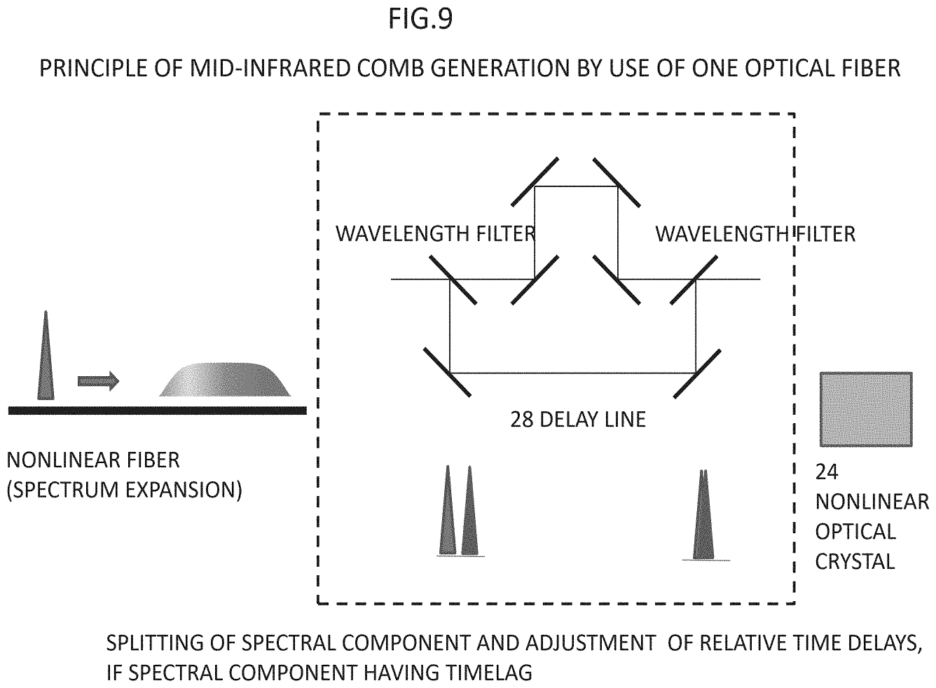

FIG. 9 illustrates the principle of mid-infrared comb generation by use of one optical fiber. A delay line 28 is described with reference to FIG. 8 and FIG. 9. The carbon isotope analysis device 1 in FIG. 8 includes a delay line 28 including a plurality of wavelength filters between the light source 23 and the nonlinear optical crystal 24. The first optical fiber 21 transmits the light from the light source 23, and the spectrum is expanded (spectrum expansion). If the spectral components have a time lag, the delay line 28 (optical path difference adjuster) splits the spectral components and adjusts the relative time delays, as illustrated in FIG. 9. The spectral components can be focused on a nonlinear crystal 25 to thereby generate a mid-infrared comb.

While such a delay line is exemplified as the wavelength filter, a dispersion medium may also be used without any limitation thereto.

### <Light Shield>

In the aforementioned embodiment, the distance between the mirrors is adjusted with the piezoelectric element 13 for generation of ring-down signals in the spectrometer 10. For generation of ring-down signals, a light shield may be provided in the light generator 20 for ON/OFF control of light incident on the optical resonator 11. The light shield may be of any type that can promptly block light having the absorption wavelength of the carbon dioxide isotope. The excitation light should be blocked within a time much shorter than the decay time of light in the optical resonator.

### [Second Aspect of Carbon Isotope Analysis Device]

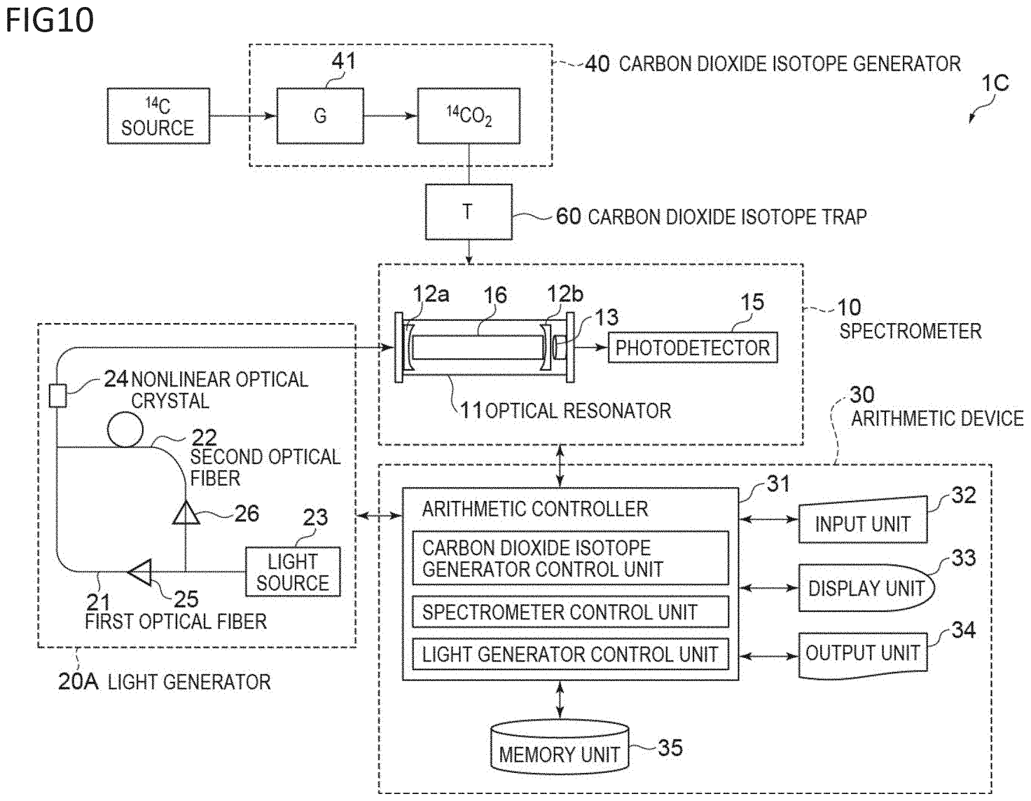

A carbon isotope analysis device 10 is obtained by replacing the light generator 20A in FIG. 1 with a light generator 200 in FIG. 10, and includes a carbon dioxide isotope generator 40, the light generator 20A and the spectrometer 10, and also the arithmetic device 30.

The light generator 20C in FIG. 10 includes a single light source 23, a first optical fiber 21 that transmits light from the light source 23, a second optical fiber 22 that, transmits light of a longer wavelength than the first optical fiber, the second optical fiber splitting from a splitting node of the first optical fiber 21 and coupling with the first optical fiber 21 at a coupling node downstream, and a nonlinear optical crystal 24 through which a plurality of light beams different in frequency are allowed to propagate through to thereby generate light at an absorption wavelength of the carbon dioxide isotope, due to the difference in frequency.

The light generator includes a first amplifier that is disposed between the splitting node and the coupling node of the first optical fiber 21, a second amplifier that is disposed between the splitting node and the coupling node of the second optical fiber and that is different in band from the first amplifier, and a nonlinear optical crystal through which are allowed to propagate through to thereby generate light at an absorption wavelength of the carbon dioxide isotope, due to the difference in frequency.

The amplifier, for example, a first amplifier 25 disposed on the route of the first optical fiber 21 is preferably an Er-doped optical fiber amplifier, and a second amplifier 26 disposed on the route of the second optical fiber 22 is preferably a Tm-doped optical fiber amplifier.

The first optical fiber 21 should preferably further include a third amplifier, more preferably a third amplifier between the first amplifier 21 and the coupling node, because the intensity of light obtained is enhanced. The third amplifier should preferably be an Er-doped optical fiber amplifier.

The first optical fiber 21 should preferably further include a wavelength-shifting fiber, more preferably a wavelength-shifting fiber between the first amplifier and the coupling node, because the intensity of light obtained is enhanced.

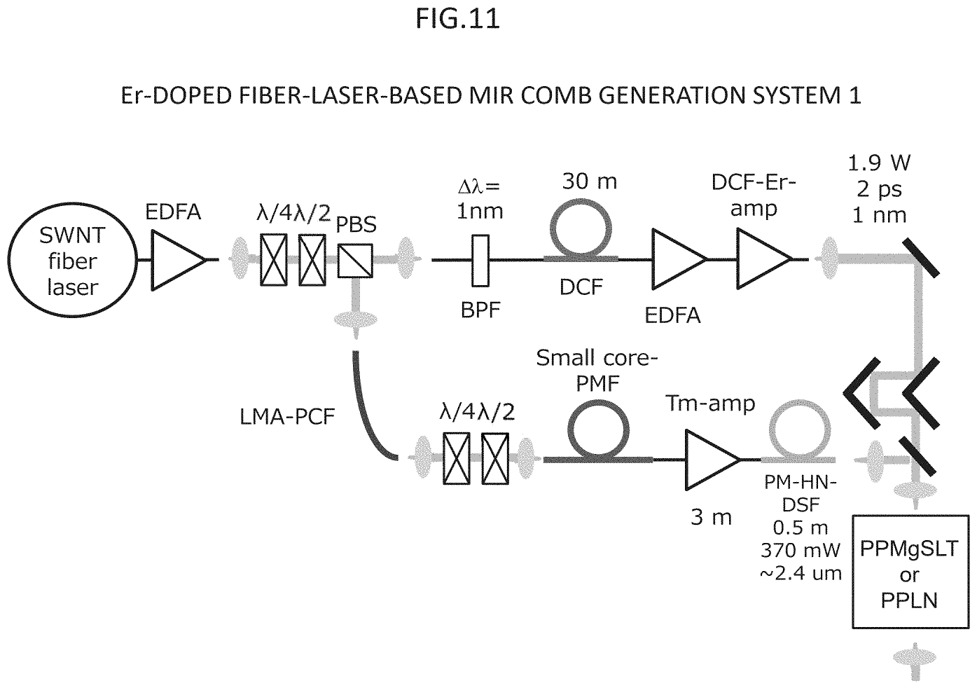

FIG. 11 illustrates an Er-doped fiber-laser-based mid-infrared (MIR) comb generation system 1. A carbon isotope analysis method by use of a carbon isotope analysis device according to a third aspect will be described with reference to FIG. 11.

The light source used is a high repetition rate ultrashort pulse fiber laser by use of a single-wall carbon nanotube (SWNT) and 980-nm LD as an excitation laser, where the wavelength of light emitted is 1.55 μm and the repeated frequency is 160 MHz. The light emitted from the light source is input as seed light, amplified by an Er-doped fiber amplifier (EDEA) and split to two beams by a polarization beam splitter (PBS).

Chirped pulse amplification is performed by an amplifier (DCF-Er-amp) using a dispersion-compensating fiber (DCF), EDFA, and an Er:Yb-doped double-clad fiber on one shorter wavelength route (first optical fiber). The delay line illustrated can also be subjected to fine correction of the wavelength.

The following is performed on other longer wavelength route (second optical fiber): the dispersion of light pulses amplified by use of a large-mode-area photonic crystal fiber (LMA-PCF) is compensated, ultrashort light pulses high in intensity are generated, the wavelength is then shifted to about 1.85 μm by a small core polarization-maintaining fiber (Small core PMF), and the light is amplified by a Tm-doped fiber amplifier (TDFA). Furthermore, wavelength conversion (expansion) is performed by a polarization maintaining highly nonlinear dispersion shifted fiber (PM-HE-DSP).

As described above, supercontincum (SC) light having an average output of 300 mW and expanding in a wavelength range from 1700 to 2400 nm (1.7 to 2.4 μm) can be generated.

Finally, difference frequency generation is performed by making each light output from the two routes, incident perpendicularly to the S1 surface of a nonlinear optical crystal (PPM SLT manufactured by Oxcie Corporation (Nonlinear Coefficient (deff)>7.5 pm/V, Typical PMT 44+/−5 degree C., AR. Coat. S1&S2 R<0.5% at 1064/532 nm, Crystal Size (T×W) 1 mm×2 mm, Crystal Length (L) 40 mm)) having a length in the longitudinal direction of 40 mm. As described above, a mid-infrared optical frequency comb of a wavelength range from 4400 to 4800 nm (4.5 μm) can be emitted from the S2 surface.

A half-value width is narrower and an intensity is higher than those in a light spectrum diagram of a mid-infrared comb, created by a conventional method. A polarization maintaining highly nonlinear dispersion shifted fiber is added to a rear stage of TDI-A to thereby not only enhance the selectivity of light of an objective wavelength, but also efficiently provide desired light having a high intensity.

Since an optical comb may be obtained in the carbon isotope analysis within the scope where the wavelength region for analysis of ¹⁴C as an analyte is covered, the present inventors have focused on the following: obtaining higher-power light with a narrower oscillation spectrum of an optical comb light source. A narrower oscillation spectrum can allow for amplification with amplifiers different in band and use of a nonlinear optical crystal long in length. The present inventors have then made studies, and as a result, have conceived that high-power irradiation light having the absorption wavelength of carbon dioxide isotope is generated based on the difference in frequency, by (A) generating a plurality of light beams different in frequency, from a single light source, (B) amplifying intensities of the plurality of light beams obtained, by use of amplifiers different in band, respectively, and (C) allowing the plurality of light beams to propagate through a nonlinear optical crystal longer in length than a conventional nonlinear optical crystal, in generation of an optical comb by use of a difference frequency generation method. The present invention has been completed based on the above finding. There has not been reported any conventional difference frequency generation method that amplifies the intensity of light with a plurality of amplifiers different in band and provides high-power irradiation light obtained by use of a crystal long in length.

Absorption of light by a light-absorbing material, in the case of a high intensity of an absorption line and also a high intensity of irradiation light, is remarkably decreased in low level corresponding to the absorption of light and appears to be saturated with respect to the effective amount of light absorption (called saturation absorption). According to a SCAR theory (Saturated Absorption CRDS), in the case where light of a 4.5-μm wavelength range, high in intensity of an absorption line, is applied to a sample such as ¹⁴CO₂ in an optical resonator, a large saturation effect is initially exhibited due to a high intensity of light accumulated in an optical resonator and a small saturation effect is subsequently exhibited due to a gradual reduction in intensity of light accumulated in an optical resonator according to progression of decay, with respect to a decay signal (ring-down signal) obtained. Thus, a decay signal where such a saturation effect is exhibited is not according to simple exponential decay. According to such a theory, fitting of a decay signal obtained in SCAR enables the decay rate of a sample and the decay rate of the back ground to be independently evaluated, and thus not only the decay rate of a sample can be determined without any influence of the variation in decay rate of the back ground, for example, due to the parasitic etalon effect, but also absorption of light by ¹⁴CO₂ can be more selectively measured due to the saturation effect of ¹⁴CO₂ larger than that of a gaseous contaminant. Accordingly, use of irradiation light higher in intensity is more expected to result in an enhancement in sensitivity of analysis. The light generator of the present invention can generate irradiation light high in intensity, and thus is expected to result in an enhancement in sensitivity of analysis in the case of use for carbon isotope analysis.

### [Third Aspect of Carbon Isotope Analysis Device]

<Light Generator Including Light Source Other than Optical Comb, as Main Light Source>

It has been conventionally considered that, since a quantum cascade laser (QCL) has perturbation of oscillation wavelength and absorption wavelengths of ¹⁴C and ¹³C are adjacent, the QCL is difficult to use as a light source of a carbon isotope analysis device for use in ¹⁴C analysis. Thus, the present inventors have uniquely developed an optical comb light source that generates an optical comb from a single light source and thus have completed a compact and convenient carbon isotope analysis device (see Patent Document 2).

The present inventors have completed a light generator that generates narrow-line width and high-output (high-intensity) light, in order to achieve a further enhancement in analytical accuracy of a carbon isotope analysis device.

The present inventors have made studies about a further application of the light generator, and as a result, have conceived that perturbation of oscillation wavelength of light generated from QCL is corrected by a beat signal measurement device where narrow-line width light generated from the light generator is used as a frequency reference. The inventors have progressively made studies based on the finding, and as a result, have completed a compact, convenient, and highly-reliable light generator where a light source other than an optical comb is adopted as a main light source, and a carbon isotope analysis device by use of the light generator.

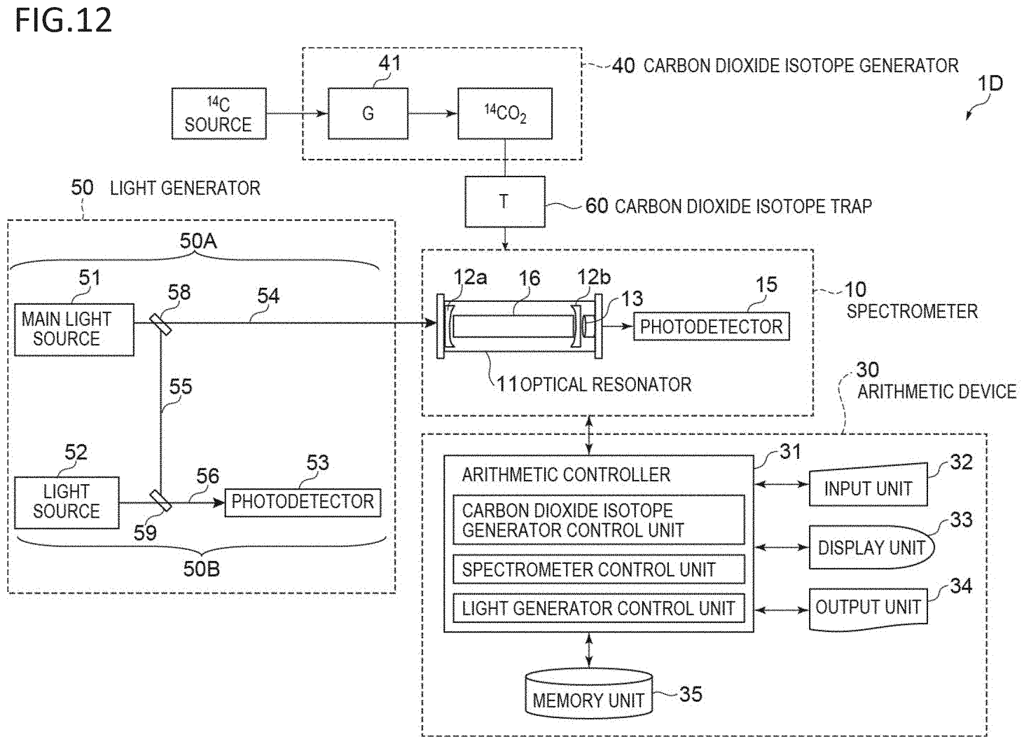

FIG. 12 schematically illustrates a carbon isotope analysis device 1D according to a third aspect. The carbon isotope analysis device 11D is obtained by replacing the light generator 20A in FIG. 1 with a light generator 50 in FIG. 12, and includes a carbon dioxide isotope generator 40, the light generator 50 and a spectrometer 10, and also an arithmetic device 30.

The light generator 50 includes:
a light generator body 50A including a main light source 51 and an optical fiber 54 that transmits light from the main light source 51; and
a beat signal measurement device 50B including an optical comb source 52 that generates an optical comb of a flux of narrow-line-width light beams where the frequency region of a light beam is 4500 nm to 4800 nm, an optical fiber 56 for beat signal measurement that transmits light from the optical comb source 52, splitters 58 and 59 disposed on optical fibers 54 and 56, respectively, an optical fiber 55 that partially splits light from the main light source 51 via the splitters 58 and 59 and transmits the resultant to such an optical fiber 56 for beat signal measurement, and a photodetector 53 that measures a beat signal generated due to the difference in frequency between light from the main light source 51 and light from the optical comb source 52.

The main light source of the carbon isotope analysis device 1C including the light generator 50 is not limited to an optical comb, can be a general-purpose light source such as QCL, and thus is increased in flexibilities of design and maintenance of the carbon isotope analysis device 1C.

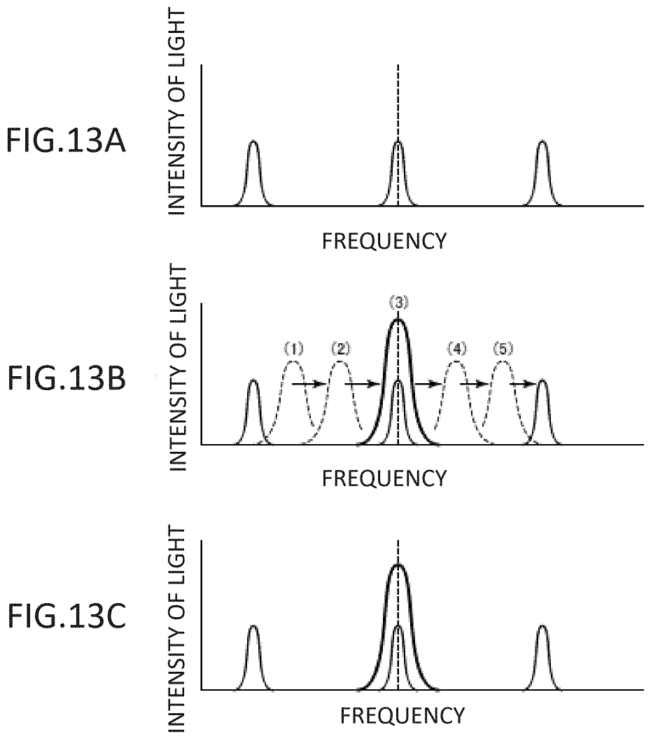

The light generator 50 illustrated in FIG. 12 can generate predetermined light to thereby allow the carbon isotope analysis to be performed with the following steps. The flow diagrams of FIGS. 13A, 13B, and 13C are used for description.
(A) An optical comb made of a flux of narrow-line-width light beams where the wavelength region of a light beam is 4500 nm to 4800 nm is generated.
(B) As illustrated in FIG. 13A, a spectrum of a light beam in the optical comb is then displayed at the center of the absorption wavelength region of a test subject, in a light spectrum diagram of intensity-versus-frequency.
(C) The light from the optical comb is transmitted through the optical fiber for beat signal measurement.
(D) The light from the light source is applied to a test subject, and the amount of light absorption is measured by an optical resonator (CRDS).
(E) The light from the light source is partially split and transmitted to the optical fiber for beat signal measurement, and a beat signal is generated based on the difference in frequency between the light from the light source and the light from the optical comb source. Such a beat signal may also be generated with scanning in a wide range of frequency as in (1), (2) . . . indicated by arrows in FIG. 13B. Such a beat signal may also be generated in a desired frequency region as illustrated in FIG. 13C,
(F) Not only the amount of light absorption, obtained in step (D), but also the wavelength of light applied to the test subject, obtained by the beat signal obtained in step (E), is recorded. An accurate amount of light absorption of the test subject is measured based on such recording.

The present invention enables accurate measurement to be realized in a simple and convenient measurement system, although no phase-locking is daringly performed by an optical comb.

### [Fourth Aspect of Carbon Isotope Analysis Device]

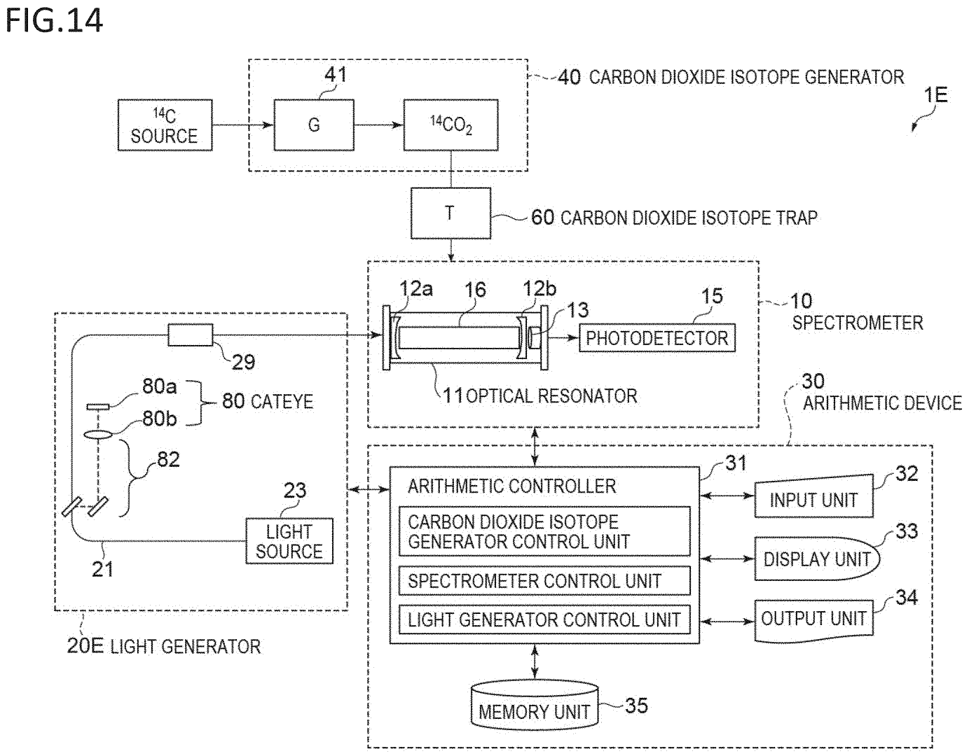

FIG. 14 is a conceptual view of a fourth embodiment of a carbon isotope analysis device. As illustrated in FIG. 14, a light generator 20E includes the light source 23, a splitter (delay line) 82 that splits light from the light source 23, and a cat eye 80 including a condenser lens 80b that focuses light from the splitter 82 and a mirror 80a that reflects light from the condenser lens 80b to thereby send the light back to the light source 23 via the condenser lens 80b and the splitter 82. The light generator 20 further includes an optical isolator 29.

The cat eye 25 allows the dependence of back reflection affecting angle adjustment to be decreased, and thus enables light to be readily again incident on QCL. The optical isolator 29 enables light to be shielded.

The light source 23 may be a mid-infrared quantum cascade laser (Quantum Cascade Laser: QCL).

It is preferred that the optical fiber 21 can transmit high intensity of ultrashort light pulses without deterioration of the optical properties of the pulse. The optical fiber 21 should preferably be composed of fused silica.

In the fourth embodiment, it is preferable to generate a laser beam from the light source 23 and transmit such light obtained, to the optical fiber 21; to split the light from the light source 23 by use of a splitter 28; to focus the light split, on a condenser lens 25b and reflect the light focused, by use of a mirror 25a; and to send the light back to the light source 23 via the mirror 25a and the splitter 28 (feedback step).

The present inventors have proposed a carbon isotope analysis device that can allow for convenient and rapid analysis of ¹⁴C, and a carbon isotope analysis method by use of the carbon isotope analysis device (see Patent Document 2). Thus, studies about microdose with ¹⁴C can be conveniently and inexpensively performed.

There is increasingly demanded a distributed-feedback (DFB) quantum-cascade laser (hereinafter may be referred to as “QCL”) system as one aspect of a mid-infrared (MIR) laser for use in ¹⁴C analysis. The reason for this is because such a system is commercially available and is easily handled due to a broad mode-hop-free tuning range of several nanometers and monomode emission of a line width of typical several MHz.

Although sufficient in the above performance in many spectroscopic applications, such a QCL system has been demanded to have a line width of 100 kHz or less laser in coupling with a high-finesse optical resonator (reflectance R>99.9%) for use in CRDS. A solution for solving the problem of such a decrease in line width is, for example, high-speed electrical signal feedback (for example, PDH lock) with a frequency discriminator, and has the problems of a need for a high-speed signal processing system and of being expensive. Furthermore, there is a need for high bandwidth modulation in a laser light source.

Thus, it has been demanded to further improve stability of a light source in ¹⁴C analysis.

The present inventors have made studies, and as a result, have focused on a method using optical feedback known as delayed self-injection, as an alternative of high-speed electrical signal feedback with a frequency discriminator. It has found that such passive feedback can be applied to QCL to thereby allow the line width of a laser to be reduced by the minimum cost. That is, the fourth embodiment described above provides a carbon isotope analysis device improved in stability of a light source, and a carbon isotope analysis method by use of the carbon isotope analysis device.

The carbon dioxide trapping system (purifier) and the light source are also described through the description of the first to fourth aspects of the carbon isotope analysis device. Both the purifier and the light source each have a compact and space-less, simple configuration. An increase in freedom of the layout of the purifier and the light source can result in a significant decrease in volume of the entire carbon isotrope analysis device.

[Carbon Isotope Analysis Method]

The analysis of radioisotope ¹⁴C as an example of the analyte will now be described. Although the carbon isotope analysis method includes no pretreatment (step (A)) of a biological sample, carbon isotope analysis is preferably performed after a pretreatment of a biological sample is performed.

(A) Biological samples, such as blood, plasma, urine, feces, and bile, containing ¹⁴C are prepared as radioisotope ¹⁴C sources. The prepared biological sample is deproteinized and thus to remove the biological carbon source. The pretreatment of the biological sample is categorized into a step of removing carbon sources derived from biological objects and a step of removing or separating the gaseous contaminant in a broad sense this embodiment, the step of removing carbon sources derived from biological objects will now be mainly described.

A microdose test analyzes a biological sample, for example, blood, plasma, urine, feces, or bile containing an ultratrace amount of ¹⁴C labeled compound. Thus, the biological sample should preferably be pretreated to facilitate the analysis. Since the ratio ¹⁴C/^{Total}C of ¹⁴C to total carbon in the biological sample is one of the parameters determining the detection sensitivity in the measurement due to characteristics of the CRDS unit, it is preferred to remove the carbon source derived from the biological objects contained in the biological sample.

Examples of deproteinization include insolubilization of protein with acid or organic solvent; ultrafiltration and dialysis based on a difference in molecular size; and solid-phase extraction. As described below, deproteinization with organic solvent is preferred, which can extract the ¹⁴C labeled compound and in which the organic solvent can be readily removed after treatment.

The deproteinization with organic solvent involves addition of the organic solvent to a biological sample to insolubilize protein. The ¹⁴C labeled compound adsorbed on the protein is extracted to the organic solvent in this process. To enhance the recovery rate of the ¹⁴C labeled compound, the solution is transferred to another vessel and fresh organic solvent is added to the residue to further extract the labeled compound. The extraction operations may be repeated several times in the case that the biological sample is feces or an organ such as lung, which cannot be homogeneously dispersed in organic solvent, the biological sample should preferably be homogenized. The insolubilized protein may be removed by centrifugal filtration or filter filtration, if necessary.

The organic solvent is then removed by evaporation to yield a dry ¹⁴C labeled compound. The carbon source derived from the organic solvent can thereby be removed. Preferred examples of the organic solvent include methanol (MeOH), ethanol (EtOH), and acetonitrile (ACN). Particularly preferred is acetonitrile.

(B) Carbon isotope analysis device 1 illustrated in FIG. 1, which includes a carbon isotope trapping system illustrated in FIG. 2, is provided. The pretreated biological sample is heated and combusted to generate gas containing carbon dioxide isotope ¹⁴CO₂ from the radioactive isotope ¹⁴C source. For example, such gas containing carbon dioxide isotope ¹⁴CO₂ is generated through a combustion tube 410 of a carbon dioxide isotope generator 40 illustrated in FIG. 2. N₂O and CO are then preferably removed from the resulting gas. N₂O and CO can also be removed together with He gas by operating a carbon isotope trapping system described below.

(C) Moisture is preferably removed from the resultant ¹⁴CO₂. For example, moisture can be removed from the ¹⁴CO₂ gas in the carbon dioxide isotope generator 40 by allowing the ¹⁴CO₂ gas to pass through a drying unit 44 and/or pass through a desiccant 46 (e.g., calcium carbonate). In addition, moisture can also be removed by cooling the ¹⁴CO₂ gas for moisture condensation. For example, moisture condensation can be made by inserting cold water into a U-shaped supply tube 48 illustrated in FIG. 2. Formation of ice or frost on the optical resonator 11, which is caused by moisture contained in the ¹⁴CO₂ gas, may lead to a reduction in reflectance of the mirrors, resulting in low detection sensitivity, and removal of moisture can improve analytical accuracy. The ¹⁴CO₂ gas is preferably cooled and then introduced into the spectrometer 10 for the subsequent spectroscopic process. Introduction of the ¹⁴CO₂ gas at room temperature significantly varies the temperature of the optical resonator, resulting in a reduction in analytical accuracy.

(D) Trap tube 61 is inserted into a Dewar flask 63 including liquid nitrogen. 65, and thus the trap tube 61 is cooled to 0° C. or less. The generated ¹⁴CO₂ is then sent into the trap tube 61, together with a carrier gas lower in freezing point than the ¹⁴CO₂. The carrier gas may be, for example, helium gas. Carbon dioxide isotope is condensed in the trap tube 61. After the ¹⁴CO₂ is condensed, gas in the trap tube 61 is removed. For example, helium gas in the trap tube 61 can be removed by closing valves 66a and 66b illustrated in FIG. 2 and operating a pump P to allow the interior of the trap tube 61 to be at vacuum. Not only the valves 66a and 66b, but also valves 66c and 66d are closed to thereby shield the carbon dioxide trap 60 from the outside. The trap tube 61 is then taken out from the Dewar flask 63, the trap tube 61 is heated to about room temperature, and the condensed ¹⁴CO₂ is gasified.

(E) The optical resonator 11 is filled with the gasified ¹⁴CO₂. The optical resonator 11 can be filled with the gasified ¹⁴CO₂ by opening the valves 66a, 66h, 66c and 66d with the pump P being operated. The ¹⁴CO₂ is preferably cooled to 273 K (0° C.) or less. The ¹⁴CO₂ can be cooled by cooling the optical resonator 11 by a Peltier element 19 to enhance the absorption intensity of excitation light. The optical resonator 11 is preferably maintained under vacuum because a reduced effect of the external temperature on the optical resonator improves analytical accuracy.

(F) A mid-infrared optical frequency comb of a wavelength range from 4.5 μm to 4.8 μm is generated as irradiation light at an absorption wavelength of the carbon dioxide isotope.

(G) The carbon dioxide isotope ¹⁴CO₂ is in resonance with the light. To improve analytical accuracy, the external vibration of the optical resonator 11 is preferably reduced by a vibration absorber to prevent a perturbation in distance between the mirrors 12a and 12h. During resonance, the downstream end of the first optical fiber 21 should preferably abut on the mirror 12a to prevent the light from coming into contact with air. The intensity of light transmitted from the optical resonator 11 is then determined. As illustrated in FIG. 5, the light may be split and the intensity of each light obtained by such splitting may be measured.

(H) The concentration of carbon isotope ¹⁴C is calculated from the intensity of the transmitted light.

### EXAMPLES

An evaluation test o£ the basic performance of a carbon dioxide trapping system illustrated in FIG. 2 was performed in the following conditions.

### Examples

[Operation Procedure]

1. Sample (Rat Urine Sample)

Three rats were prepared, a cage was washed with a small amount of distilled water every 24 hours, and such distilled water used for the washing was combined to 100 g and defined as a urine sample (500 uL/collection) from each of the rats. Such a urine sample was collected from each of the rats at 8 time points in total. Such 24 samples obtained were subjected to the following experiment.

2. Carbon Dioxide Isotope Generation

Each sample was incorporated into a tin capsule or tin foil, and then oxidized and combusted in the following carbon dioxide isotope generation conditions, by use of an organic elemental analyzer (hereinafter may be referred to as “EA”, trade name: “Vario MICRO cube” manufactured by Elementar), thereby providing carbon dioxide isotope.

<Carbon Dioxide Isotope Generation Conditions>
Combustion temperature: 950° C. (instantaneous maximum: 1800° C.)
Reduction temperature: 600° C.
Carrier gas: He
Flow rate: 200 mL/min
Amount of oxygen supplied: 30 mL/min for 70 to 80 seconds
Oxidation catalyst: copper oxide
Reduction catalyst: reduced copper
Halogen removal catalyst: silver
Dehumidifier: Sicapent

3. Obtaining of Carbon Dioxide Isotope Partial Pressure

After sample gas was purified by use of a carbon isotope analysis device including a carbon dioxide trapping system illustrated in FIG. 2, the sample gas was supplied into an optical resonator, and the partial pressure value of carbon dioxide isotope in the optical resonator was measured.

The average values of the resultant measurement results of the 24 samples (3 individuals×8 time points) were as follows: the average amount of carbon: 2.2 mgC/500 uL and the average partial pressure: 80.4%.

### Comparative Examples

[Operation Procedure]

1. Sample (Glucose Sample)

Each glucose sample having an amount of carbon of 0 to 96.2 (mgC), described below, was prepared as a sample.

2. Carbon Dioxide Isotope Generation and Obtaining of Partial Pressure

Carbon dioxide isotope was generated from each glucose sample in the same manner as in Examples except that no sample gas purification was performed by use of the carbon dioxide trapping system, and the partial pressure of the carbon dioxide isotope in the optical resonator was then measured.

The resultant partial pressure value of the carbon dioxide isotope relative to the amount of carbon, with respect to each sample, is shown in Table 1.

TABLE 1

| Amount of carbon (mgC) | CO₂ partial pressure (%) |
|---|---|
| 0 | 0.04 |
| 0.05 | 0.97 |
| 0.05 | 1.00 |
| 0.11 | 1.79 |
| 0.11 | 1.79 |
| 0.57 | 6.92 |
| 0.57 | 6.15 |
| 1.09 | 9.23 |
| 1.13 | 9.23 |
| 1.15 | 10.0 |
| 2.03 | 16.0 |
| 2.1 | 15.6 |
| 4.83 | 30.4 |
| 5.01 | 31.3 |
| 8.23 | 36.5 |
| 9.62 | 48.0 |

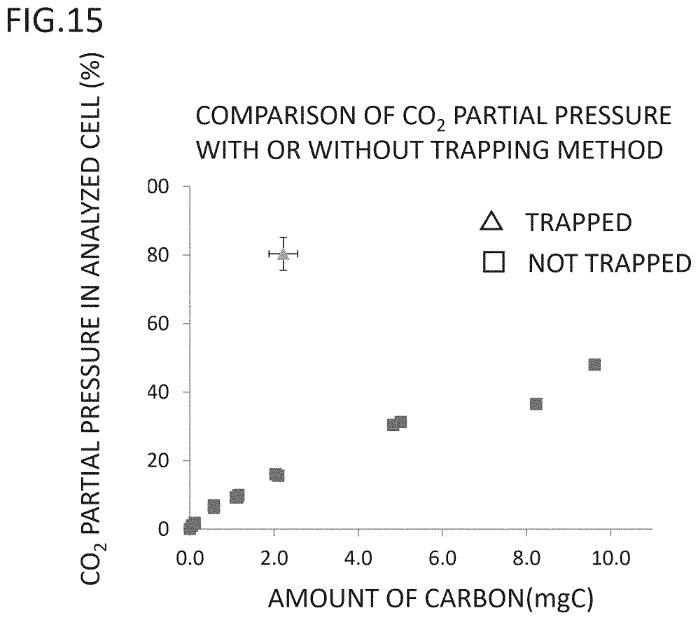

The results obtained in Examples and Comparative Examples are collectively illustrated in FIG. 15. As illustrated in FIG. 15, Examples where sample gas purification was performed by use of the carbon dioxide trapping system each had a high partial pressure of carbon dioxide isotope, of about 80%, while having a low concentration of carbon, an amount of carbon of about 2.0 (mgC). On the other hand, Comparative Examples where no sample gas purification was performed each had a partial pressure of carbon dioxide isotope, of about 40%, regardless of an amount of carbon of about 4 times those in Examples.

It was confirmed from the foregoing that the partial pressure of carbon dioxide isotope in the optical resonator was increased by performing sample gas purification by use of the carbon dioxide trapping system.

Although the carbon isotope analysis method according to the first aspect has been described above, the configuration of the carbon isotope analysis method should not be limited to the embodiment described above, and various modifications may be made. Other aspects of the carbon isotope analysis method will now be described by focusing on modified points from the first aspect.

### Other Embodiments

Although the embodiment of the present invention has been described above, the descriptions and drawings as part of this disclosure should not be construed to limit the present invention. This disclosure will enable those skilled in the art to find various alternative embodiments, examples, and operational techniques.

The carbon isotope analysis device according to the embodiment has been described by focusing on the case where the analyte as a carbon isotope is radioisotope ¹⁴_{C}. The carbon isotope analysis device can analyze stable isotopes ¹²C and ¹³C besides radioisotope ¹⁴C. In such a case, excitation light of 2 μm or 1.6 μm is preferably used in, for example, absorption line analysis of ¹²CO₂ or ¹³CO₂ based on analysis of ¹²C or ¹³C.

In the case of absorption fine analysis of ¹²CO₂ or ¹³CO₂, the distance between the mirrors is preferably 10 to 60 cm, and the curvature radius of the mirrors is preferably equal to or longer than the distance therebetween.

Although the carbon isotopes ¹²C, ¹³C, and ¹⁴C exhibit the same chemical behaviors, the natural abundance of ¹⁴C (radioisotope) is lower than that of ¹²C or ¹³C (stable isotope). Artificial enrichment of the radioisotope ¹⁴C and accurate analysis of the isotope can be applied to observation of a variety of reaction mechanisms.

The carbon isotope analysis device according to the embodiment may further include a third optical fiber configured from a nonlinear fiber that splits from a first optical fiber and couples with the first optical fiber, downstream of a splitting node. Such first to third optical fibers can be combined to thereby generate two or more various light beams different in frequency.

A medical diagnostic device or environmental measuring device including the configuration described above in the embodiment can be produced as in the carbon isotope analysis device. The light generator described the embodiments can also be used as a measuring device.

An optical frequency comb corresponds to a light source where longitudinal modes of a laser spectrum are arranged at equal frequency intervals at a very high accuracy, and is expected to serve as a novel, highly functional light source in the fields of precision spectroscopy and high-accuracy distance measurement. Since many absorption spectrum bands of substances are present in the mid-infrared region, it is important to develop a mid-infrared optical frequency comb light source. The above light generator can be utilized in various applications.

As described above, the present invention certainly includes, for example, various embodiments not described herein. Thus, the technological range of the present invention is defined by only claimed elements o£ the present invention in accordance with the proper claims through the above descriptions.

### REFERENCE SIGNS LIST

1 carbon isotope analysis device
10 spectrometer
11 optical resonator
12 mirror
13 piezoelectric element
14 diffraction grating
15 photodetector
16 cell
18 vacuum device
19 Peltier element
20A, 20B light generator
21 first optical fiber
22 second optical fiber
23 light source
24 nonlinear optical crystal
25 first amplifier
26 second amplifier
28 delay line
30 arithmetic device
40 carbon dioxide isotope generator
50 light generator
50A light generator body
51 main light source
52 light source
54 optical fiber
58 splitter
50B beat signal measurement device
52 optical comb source
53 photodetector
55, 56 optical fiber
59 splitter
60 carbon dioxide trap
80 cat eye

1. A carbon isotope analysis device comprising:
a carbon dioxide isotope generator provided with a combustion unit that generates gas containing carbon dioxide isotope from carbon isotope, and a carbon dioxide isotope purifying unit;
a spectrometer comprising an optical resonator having a pair of mirrors, and a photodetector that determines intensity of light transmitted from the optical resonator;
a carbon dioxide trap comprising a cooler for freezing the carbon dioxide isotope, the carbon dioxide trap being disposed between the carbon dioxide isotope generator and the spectrometer; and
a light generator.

2. A carbon isotope analysis device comprising:
a carbon dioxide isotope generator provided with a combustion unit that generates gas containing carbon dioxide isotope from carbon isotope, and a carbon dioxide isotope purifying unit, the carbon dioxide isotope purifying unit comprising a gaseous contaminant separating unit, a concentrating unit of the carbon dioxide isotope, and a dehumidifying unit;
a spectrometer comprising an optical resonator having a pair of mirrors and a cooler for prevention of noise generation, and a photodetector that determines intensity of light transmitted from the optical resonator;
a carbon dioxide trap comprising a cooler for freezing the carbon dioxide isotope, the carbon dioxide trap being disposed between the carbon dioxide isotope generator and the spectrometer; and
a light generator.

3. The carbon isotope analysis device according to claim 1, wherein the light generator comprises a light generator comprising a single light source, a splitter that splits light from the light source, a condenser lens that focuses light from the splitter, and a mirror that reflects light from the condenser lens to send the light back to the light source via the condenser lens and the splitter.

4. The carbon isotope analysis device according to claim 1, wherein the light generator comprises:
a light generator body having a main light source and an optical fiber that transmits light from the main light source; and
a beat signal measurement device comprising an optical comb source that generates an optical comb made of a flux of narrow-line-width light beams where the wavelength region of a light beam is 4500 nm to 4800 nm, an optical fiber for beat signal measurement, the optical fiber transmitting light from the optical comb source, a splitter that is disposed on the optical fiber that transmits light from the main light source, an optical fiber that allows light from the main light source to be partially split and transmitted to the optical fiber for beat signal measurement via the splitter, and a photodetector that measures a beat signal generated due to the difference in frequency between light from the main light source and light from the optical comb source.

5. The carbon isotope analysis device according to claim 4, wherein the light source is a mid-infrared quantum cascade laser.

6. The carbon isotope analysis device according to claim 1, wherein the light generator comprises:
a single light source;
a first optical fiber that transmits first light from the light source;
a second optical fiber that generates second light of a longer wavelength than the first light, the second optical fiber splitting from a splitting node of the first optical fiber and coupling with the first optical fiber at a coupling node downstream;
a first amplifier that is disposed between the splitting node and the coupling node of the first optical fiber;
a second amplifier that is disposed between the splitting node and the coupling node of the second optical fiber and that is different in band from the first amplifier; and
a nonlinear optical crystal that allows a plurality of light beams different in frequency to propagate through to thereby generate a mid-infrared optical frequency comb of a wavelength range from 4.5 μm to 4.8 μm, from the difference in frequency, as light at an absorption wavelength of the carbon dioxide isotope.

7. A carbon isotope analysis method, comprising the steps of:
generating carbon dioxide isotope from carbon isotope;
cooling a carbon dioxide trap to 0° C. or less;
sending the carbon dioxide isotope and gas containing carrier gas lower in freezing point than the carbon dioxide isotope, into the carbon dioxide trap, thereby condensing the carbon dioxide isotope;
removing gas in the carbon dioxide trap;
heating the carbon dioxide trap with the carbon dioxide trap being shielded from the outside, thereby gasifying the condensed carbon dioxide isotope;
filling an optical resonator with the gasified carbon dioxide isotope;
generating a mid-infrared optical frequency comb of a wavelength range from 4.5 μm to 4.8 μm, as irradiation light at an absorption wavelength of the carbon dioxide isotope;
measuring the intensity of the transmitted light generated by resonance of the carbon dioxide isotope excited by the irradiation light; and
calculating the concentration of the carbon isotope from the intensity of the transmitted light.

8. The carbon isotope analysis method according to claim 7, wherein the carbon dioxide trap is cooled to the freezing point or less, of the carbon dioxide isotope in the cooling step.

9. The carbon isotope analysis according to claim 7, wherein the carrier gas is helium (He) gas.

10. The carbon isotope analysis method according to claim 8, wherein the carrier gas is helium (He) gas.

11. The carbon isotope analysis device according to claim 2, wherein the light generator comprises a light generator comprising a single light source, a splitter that splits light from the light source, a condenser lens that focuses light from the splitter, and a mirror that reflects light from the condenser lens to send the light back to the light source via the condenser lens and the splitter.

12. The carbon isotope analysis device according to claim 2; wherein the light generator comprises:
a light generator body having a main light source and an optical fiber that transmits light from the main light source; and
a beat signal measurement device comprising an optical comb source that generates an optical comb made of a flux of narrow-line-width light beams where the wavelength region of a light beam is 4500 nm to 4800 nm, an optical fiber for beat signal measurement, the optical fiber transmitting light from the optical comb source, a splitter that is disposed on the optical fiber that transmits light from the main light source, an optical fiber that allows light from the main light source to be partially split and transmitted to the optical fiber for beat signal measurement via the splitter, and a photodetector that measures a beat signal generated due to the difference in frequency between light from the main light source and light from the optical comb source.

13. The carbon isotope analysis device according to claim 12, wherein the light source is a mid-infrared quantum cascade laser.

14. The carbon isotope analysis device according to claim 2, wherein the light generator comprises:
a single light source;
a first optical fiber that transmits first light from the light source;
a second optical fiber that generates second light of a longer wavelength than the first light, the second optical fiber splitting from a splitting node of the first optical fiber and coupling with the first optical fiber at a coupling node downstream;
a first amplifier that is disposed between the splitting node and the coupling node of the first optical fiber;
a second amplifier that is disposed between the splitting node and the coupling node of the second optical fiber and that is different in band from the first amplifier; and
a nonlinear optical crystal that allows a plurality of light beams different in frequency to propagate through to thereby generate a mid-infrared optical frequency comb of a wavelength range from 4.5 μm to 4.8 μm, from the difference in frequency, as light at an absorption wavelength of the carbon dioxide isotope.
